(19) United States
(12) Patent Application Publication
(10) Pub. No.: US 2009/0290308 A1
(43) Pub. Date: Nov. 26, 2009

(54) Heat sink for chips

(75) Inventors: Wei-Hau Chen, Taipei County (TW); Steven Yen, Taipei County (TW)

Correspondence Address: Wei-Hau Chen, P.O.Box 44-2049, Taipei, 10668, TW

(73) Assignee: CompTake Technology Inc.

(21) Appl. No.: 12/213,598

(22) Filed: Jun. 23, 2008

(30) Foreign Application Priority Data
May 23, 2008 (TW) 097209082

(51) Int. Cl. H05K 7/20

(52) U.S. Cl. 361/697

(57) ABSTRACT

A heat sink includes a first heat dispensing unit including multiple heat dispensing plates between which chips are clamped therebetween. A base board has a first extension portion and a second extension portion extending from two ends thereof. A second heat dispensing unit is fixed on a top of the base board. A first clamping member is integrally connected to the first extension portion and a second clamping member is removably connected to the second extension portion. The first and second clamping members connect the base board to the first heat dispensing unit.

### BACKGROUND OF THE INVENTION

(1) Field of the Invention

The present invention relates to a heat sink for chips and two clamping members connect a base board to first heat dispensing units clamping the chips and the second dispensing units are fixed to the base board.

(2) Description of the Prior Art

The chips used in electronic devices such as computers generate a significant heat during high speed operation and the heat may damage the chips and slow down the speed that the CPU operates. A conventional way to remove heat from the chip is to provide two heat dispensing plates between which the chip is clamped, the heat generated from the chip is conducted to the heat dispensing plates and escapes to the air via the heat dispensing plates.

However, the latest chips generate much heat with higher temperature than those made by old technology so that the conventional heat dispensing plates cannot remove the heat efficiently. This is because the area that heat is transferred from the chip is insufficient and the conventional heat dispensing plates can only remove a certain amount of heat because of limited heat dispensing area. Extra heat removing units are needed and because the limited space available in the computers so that how to provide a high efficiency heat removing units is an important problem.

The present invention intends to provide a heat sink for efficiently removing heat from the chips and includes two heat dispensing units, one of the heat dispensing units clamps the chips and the other heat dispensing unit is connected on the first heat dispensing unit by using a base board and two clamping members. One of the clamping members is integrally formed with one end of the base board and the other clamping member is removably connected to the other end of the base board. The two clamping members respectively engaged with two ends of the first heat dispensing unit such that heat from the chips can be efficiently removed.

### SUMMARY OF THE INVENTION

The present invention relates to a heat sink which comprises a first heat dispensing unit which includes multiple heat dispensing plates so as to clamp chips therebetween. A base board is mounted on a top of the first heat dispensing unit and has a first extension portion and a second extension portion extending from two ends thereof. A second heat dispensing unit is fixed on a top of the base board. A first clamping member is integrally connected to the first extension portion and a second clamping member is removably connected to the second extension portion. The first and second clamping members connect the base board to the first heat dispensing unit.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show the chips and the heat sink of the present invention;

FIG. 2 is a perspective view to show the heat sink of the present invention and the chips;

FIG. 3 is an exploded view to show the chips and a second embodiment of the heat sink of the present invention;

FIG. 4 is a perspective view to show the connection of the chips and the heat sink in FIG. 3 of the present invention;

FIG. 5 is an exploded view to show a third embodiment of the heat sink of the present invention and the chips, and

FIG. 6 is a perspective view to show the connection of the chips and the heat sink in FIG. 5 of the present invention.

### DETAILED DESCRIPTION OF THE PREFERRED EMBODIMENTS

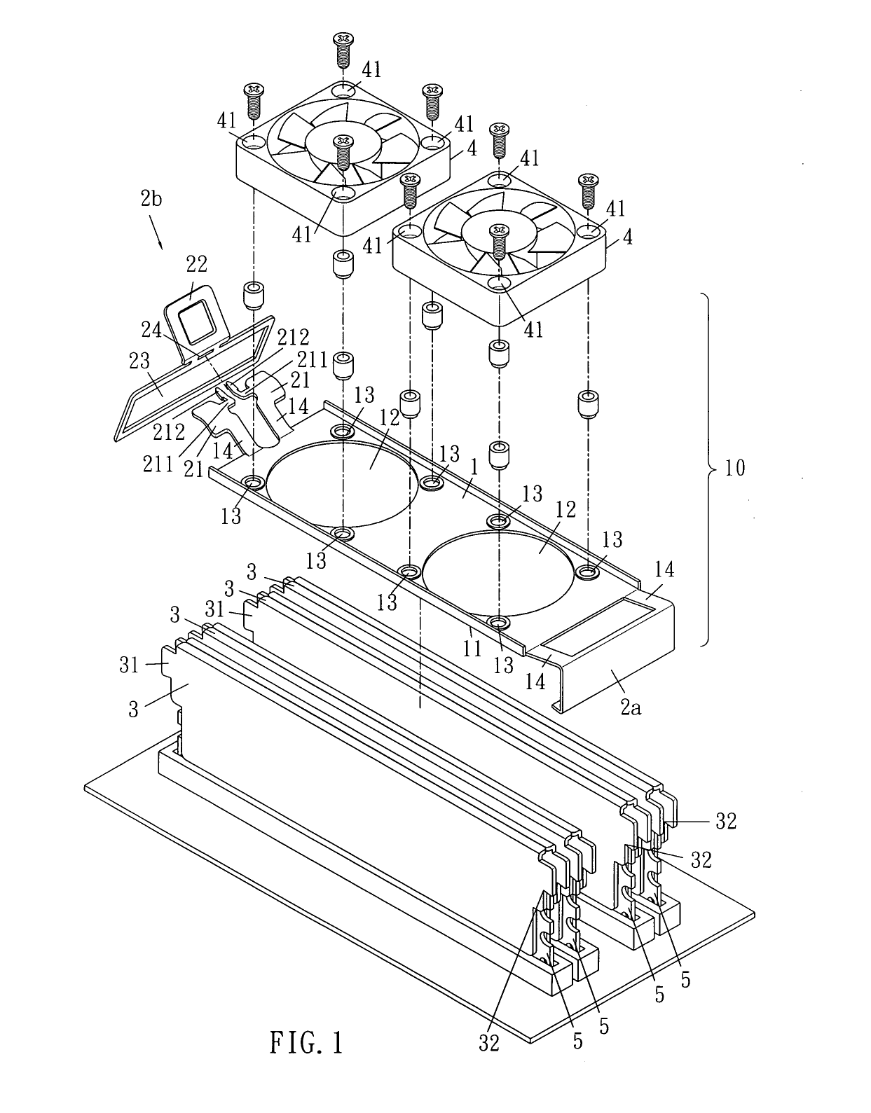

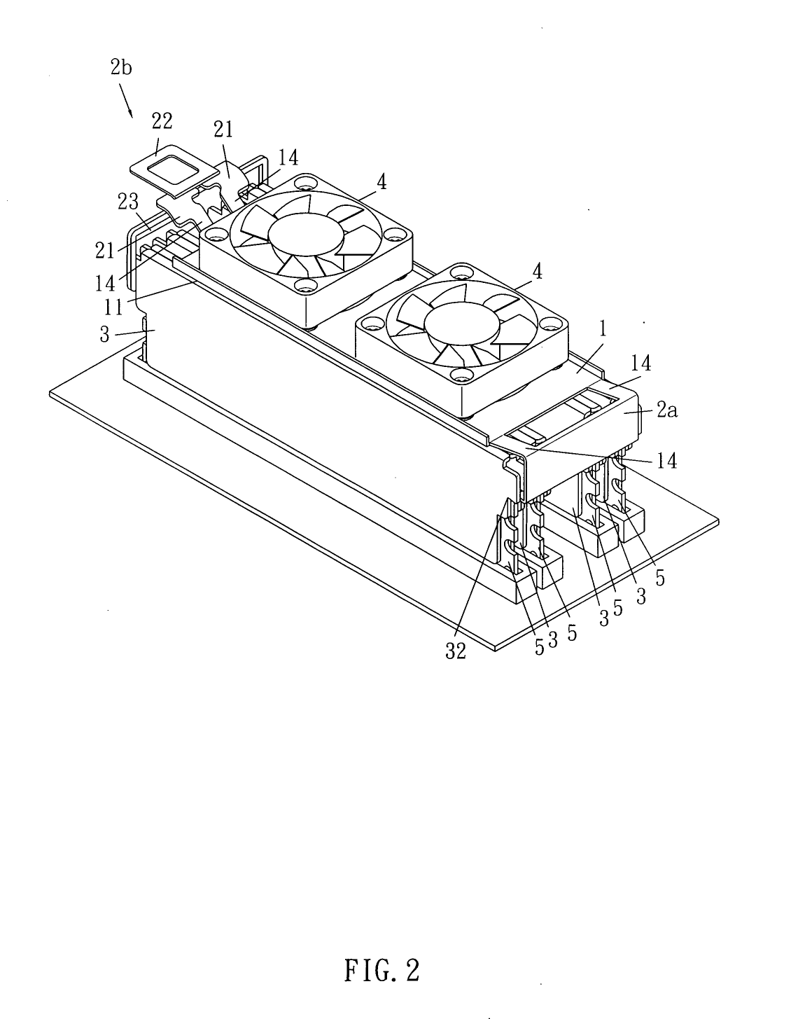

Referring to FIGS. 1 and 2, the heat sink 10 for removing heat from the chips 5 of the present invention comprises multiple first heat dispensing units 3, a base board 1, two second heat dispensing units 4 and two clamping members 2a, 2b.

The first heat dispensing units 3 each include multiple heat dispensing plates between which the chips 5 are clamped. Each heat dispensing plate of the first heat dispensing unit 3 includes recesses 32 and protrusions 31 on two ends thereof.

The base board 1 has a contact surface 11 defined in an underside of the base board 1 and the contact surface 11 is shaped to match with the top of the first heating dispensing units 3, such that the base board 1 can be directly mounted on the top of the first heating dispensing units 3. Two holes 12 are defined through the base board 1 and a plurality of threaded holes 13 are located around the holes 12. The base board 1 has a first extension portion 14 and a second extension portion 140 extending from two ends thereof.

The second heat dispensing units 4 are fixed on a top of the base board 1 by extending bolts through passages 41 in the second heat dispensing units 4 and connected to the threaded holes 13 in the base board 1. The second heat dispensing units 4 are located corresponding to the holes 12. The two clamping members 2a, 2b connect the base board 1 to the first heat dispensing units 3.

The two clamping members are a first clamping member 2a and a second clamping member 2b, wherein the first clamping member 2a is an L-shaped plate which is integrally connected to the first extension protrusion 14. The first clamping member 2a hook the recesses 32 of the first heat dispensing unit 3. The second clamping member 2b is engaged with the recesses 32. The second extension portion 140 of the base board 1 includes two parts and each part has an end portion 21 at a distal end thereof. Each end part includes an L-shaped insertion 211. The second clamping member 2b includes a handle 22 and a rectangular frame 23 is connected to the handle 22 by a neck portion. A slot 24 is defined through the neck portion and the two insertions 211 are removably engaged with the slot 24. The protrusions 31 of the first heat dispensing unit 3 are engaged with the rectangular frame 23.

The heat generated from the chips 5 is conducted to the heat dispensing plates of the first heat dispensing unit 3 and then brought out from the first dispensing unit 3 by the second heat dispensing units 4 via the holes 12. In this embodiment, the second heat dispensing units 4 are fans.

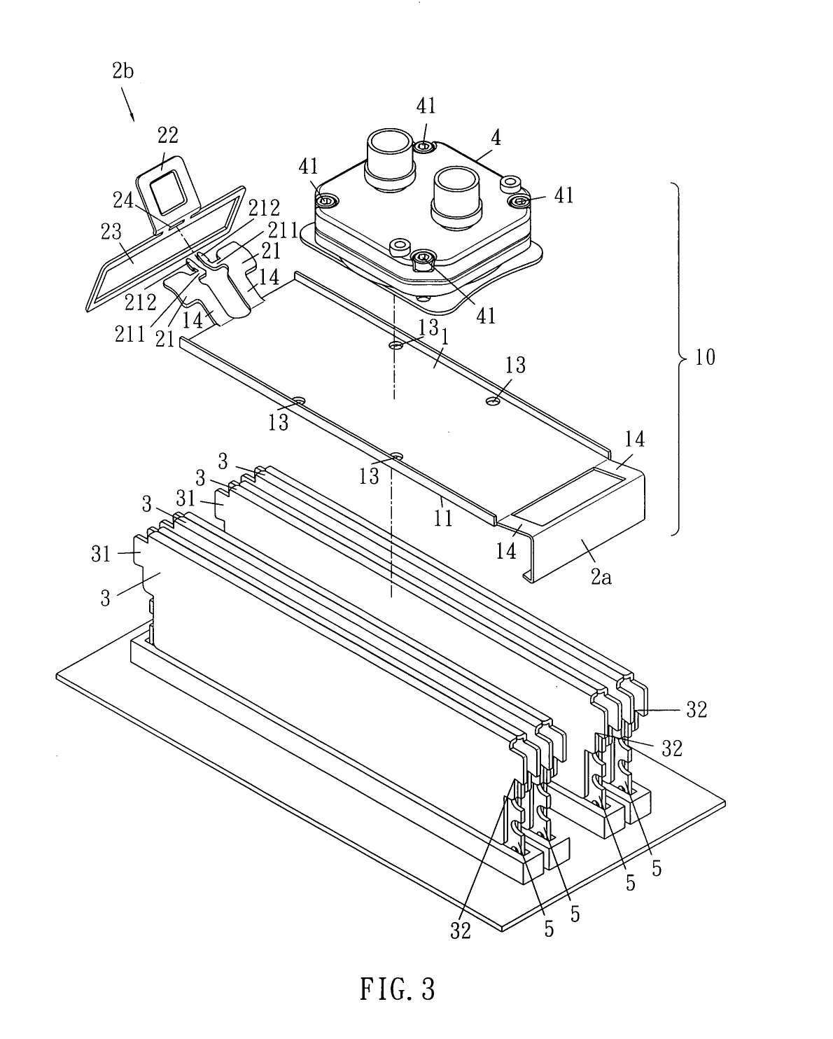

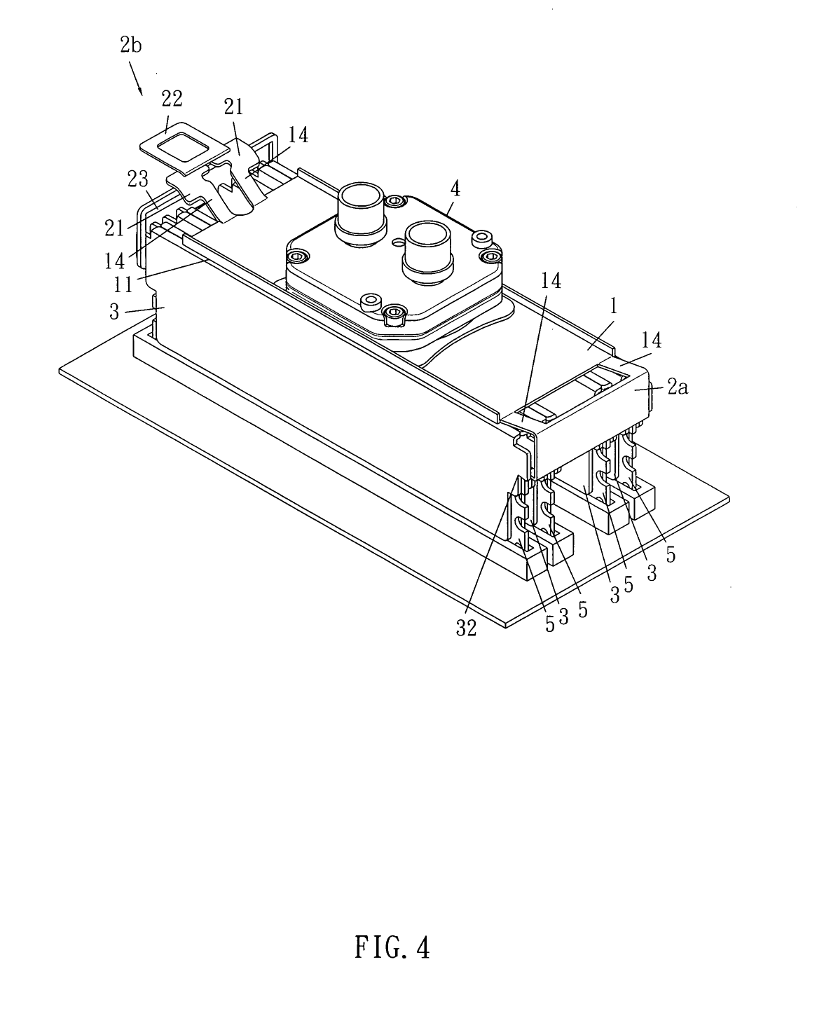

FIGS. 3 and 4 show the second embodiment of the heat sink 10 of the present invention, wherein the base board 1 does not have the holes 12 as shown in FIG. 1 and the second heat dispensing unit 4 is a water-cooling unit.

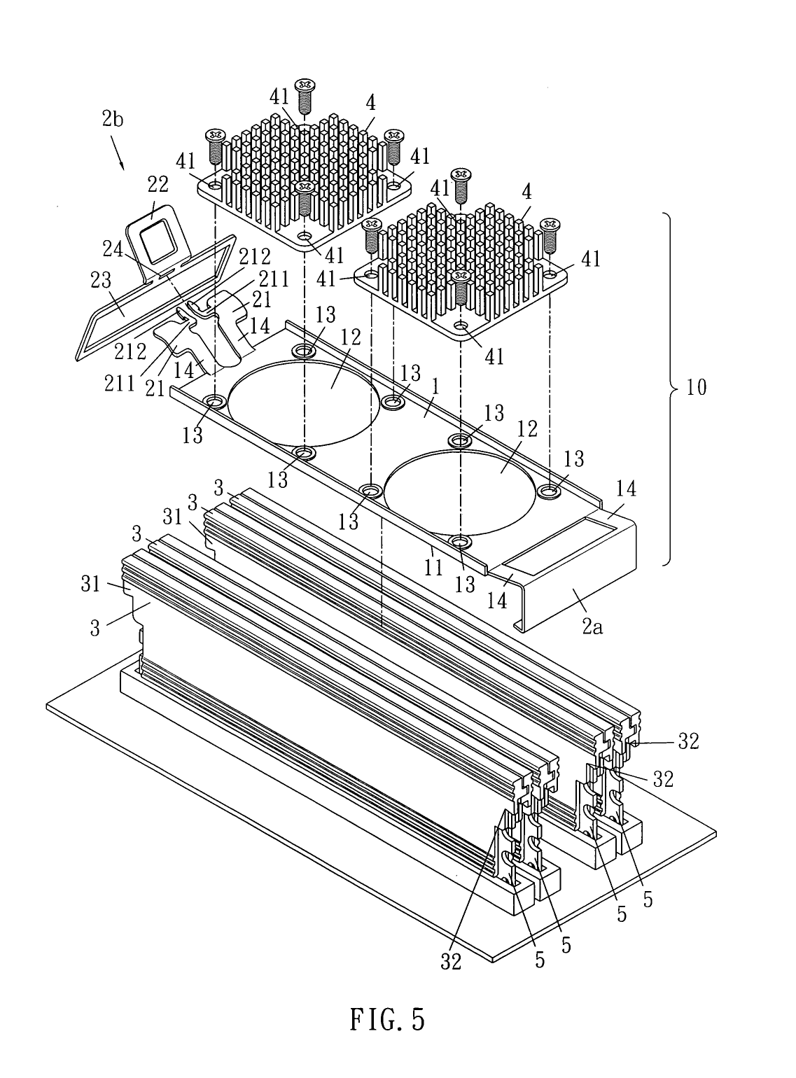

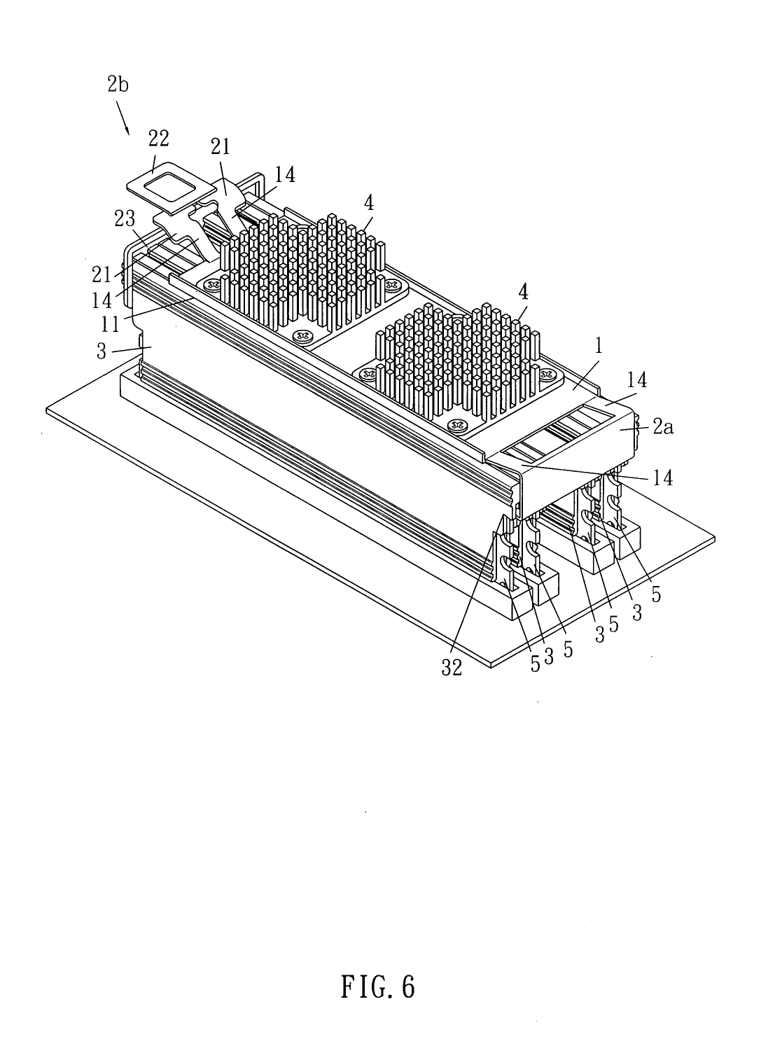

As shown in FIGS. 5 and 6, the third embodiment of the heat sink 10 of the present invention is disclosed wherein the second heat dispensing units 4 are two aluminum extruding members and each of which includes multiple fins extending therefrom so as to increase area for releasing the heat.

The second heat dispensing units 4 are first fixed to the base board 1 and the base board 1 is then connected with the first heat dispensing units 3 by the clamping members 2a, 2b. The first and second heat dispensing units 4 are in contact with each other so as to perform an efficient heat dispensing feature.

While we have shown and described the embodiment in accordance with the present invention, it should be clear to those skilled in the art that further embodiments may be made without departing from the scope of the present invention.

What is claimed is:

1. A heat sink comprising:
a first heat dispensing unit including multiple heat dispensing plates which are adapted to clamp chips therebetween;
a base board having a contact surface defined in an underside of the base board, the contact surface being shaped to directly match with a top of the first heat dispensing unit, the base board having a first extension portion and a second extension portion extending from two ends thereof, a second heat dispensing unit fixed on a top of the base board, and
a first clamping member integrally connected to the first extension portion and a second clamping member removably connected to the second extension portion, the first and second clamping members connecting the base board to the first heat dispensing unit.

2. The heat sink as claimed in claim 1, wherein each heat dispensing plate of the first heat dispensing unit includes recesses and protrusions on two ends thereof, the first clamping member hooks the protrusions and the second clamping member is engaged with the recesses.

3. The heat sink as claimed in claim 1, wherein the base board includes a hole defined therethrough and the second heat dispensing unit is located corresponding to the hole.

4. The heat sink as claimed in claim 1, wherein the first clamping member is an L-shaped plate integrally connected to the first extension protrusion.

5. The heat sink as claimed in claim 1, wherein the second extension portion includes two parts and each part has an end portion at a distal end thereof, each end part includes an L-shaped insertion, the second clamping member includes a handle and a rectangular frame is connected to the handle by a neck portion, a slot is defined through the neck portion and the two insertions are removably engaged with the slot, the protrusions are engaged with the rectangular frame.

6. The heat sink as claimed in claim 1, the second heat dispensing unit is a fan.

7. The heat sink as claimed in claim 1, the second heat dispensing units is a water-cooling unit.

8. The heat sink as claimed in claim 1, the second heat dispensing unit is an aluminum extruding member.

9. The heat sink as claimed in claim 8, wherein the aluminum extruding member includes multiple fins formed thereto.
